(19) United States
(12) Patent Application Publication
(10) Pub. No.: US 2023/0317511 A1
(43) Pub. Date: Oct. 5, 2023

(54) SEMICONDUCTOR ASSEMBLIES WITH SYSTEM AND METHOD FOR SMOOTHING SURFACES OF 3D STRUCTURES

(71) Applicant: Micron Technology, Inc., Boise, ID (US)

(72) Inventors: Andrew M. Bayless, Boise, ID (US); Brandon P. Wirz, Boise, ID (US); Owen R. Fay, Meridian, ID (US)

(21) Appl. No.: 18/111,496

(22) Filed: Feb. 17, 2023

Related U.S. Application Data
(60) Provisional application No. 63/315,861, filed on Mar. 2, 2022.

(51) Int. Cl. H01L 21/768; H01L 21/02; G03F 7/004; G03F 7/20

(52) U.S. Cl. CPC H01L 21/76801; G03F 7/004; G03F 7/20; H01L 21/02348

(57) ABSTRACT

A method for smoothing structures formed of curable materials on a semiconductor device includes applying a layer of photo-responsive material on a substrate. The photo-responsive material is exposed to ultraviolet light through a grayscale gradient mask. Subsequent to removing unwanted portions of the photo-responsive material, the photo-responsive material that remains on the substrate is cured. During the curing process, the temperature is increased from a starting temperature to a final cure temperature over a first time period that allows the photo-responsive material to cross-flow. The temperature of the photo-responsive material is maintained at approximately the final cure temperature for a second time period, and then the temperature of the photo-responsive material is decreased to a predetermined finish temperature over a third time period.

### CROSS-REFERENCE TO RELATED APPLICATION(S)

The present application claims priority to U.S. Provisional Pat. Application No. 63/315,861, filed Mar. 2, 2022, the disclosure of which is incorporated herein by reference in its entirety.

### TECHNICAL FIELD

The present technology is directed to semiconductor device packaging. More particularly, some embodiments of the present technology relate to techniques for creating smooth structures in situ using grayscale photolithography.

### BACKGROUND

Semiconductor dies, including memory chips, microprocessor chips, logic chips and imager chips, that are used in flexible devices have interconnects that can crack or break, resulting in failure. Also, some devices that require high precision and smooth surfaces currently need to be fabricated separately and then assembled into semiconductor device assemblies.

### BRIEF DESCRIPTION OF THE DRAWINGS

Many aspects of the present technology can be better understood with reference to the following drawings. The components in the drawings are not necessarily to scale. Instead, emphasis is placed on illustrating the principles of the present technology.

FIGS. 1A and 1B are views of a semiconductor device assembly that includes a three-dimensional (3D) structure that can be formed in accordance with embodiments of the present technology.

FIG. 2A is an example of a gradient mask 200 that can be used to create a sloped, curving structure of photo-responsive material in accordance with embodiments of the present technology.

FIG. 2B shows a portion of an initial structure formed of photo-responsive material that has been cured in accordance with embodiments of the present technology.

FIG. 2C illustrates a second structure formed over an outer surface of the initial structure of FIG. 2B in accordance with embodiments of the present technology.

FIG. 3 is a flow-chart of a method for smoothing a gradient of an outer surface of an initial structure made of photo-responsive material during the curing process in accordance with embodiments of the present technology.

FIGS. 4A and 4B show standard hard bake cure profiles and smoothing hard bake cure profiles for a polyimide material in accordance with embodiments of the present technology.

FIG. 5 is a flow-chart of a method for building a structure on top of or over the smoothed photo-responsive material of the initial structure in accordance with embodiments of the present technology.

FIG. 6 is a schematic view showing a system that includes a semiconductor device assembly configured in accordance with an embodiment of the present technology.

### DETAILED DESCRIPTION

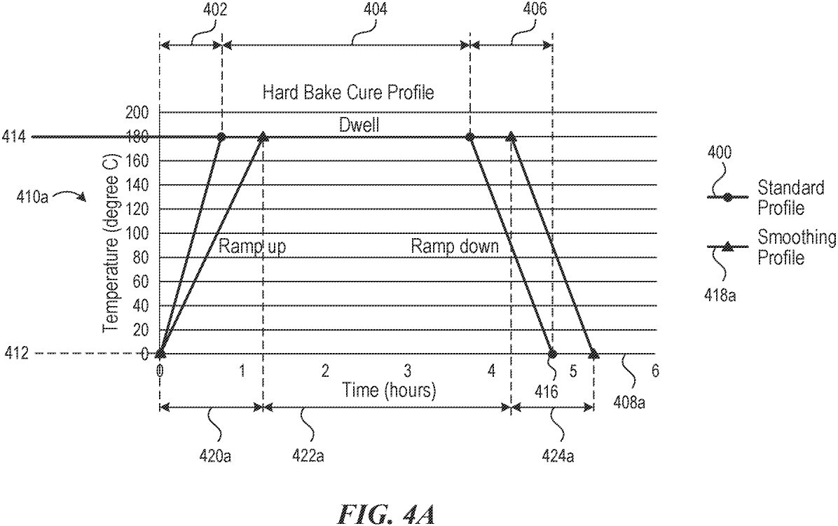

During a grayscale photolithography process, a structure can be formed of a photo-responsive and curable material, such as photoresist or a dielectric-like polyimide. The structure can be permanent if made with a product such as polyimide, or temporary if formed with photoresist. The curing process generally includes three consecutive time periods during which the temperature is adjusted to predetermined parameters, such as a ramp-up period, a dwell period, and a ramp-down period, discussed in detail further below in FIG. 3. In the ramp-up period, a temperature ramping rate can be set to increase the temperature from an acceptable low temperature (e.g., zero degrees Celsius or other initial working temperature) to a final cure temperature. The final cure temperature is held for a dwell period, after which the temperature ramping rate is set to decrease the temperature back to zero degrees Celsius or other acceptable finish temperature over the ramp-down period. Some curing processes may include additional time periods, such as one or more additional dwell periods at different temperatures within the ramp-up period.

In some embodiments, the temperature ramping rate during the ramp-up period is set to allow the photo-responsive material to soften prior to cross-linking, thus refining slopes and edges in the surface of the material. Using a lower/slower ramp rate than was used in previous applications allows the photo-responsive material to cross-flow before it is set or cross-linked. The cross-flow of the photo-responsive material softens or diminishes the “stair-step” or sawtooth topology created by the grayscale photolithography process, resulting in an exposed outer surface of the photo-responsive material that has a smoother gradient while utilizing a single photo exposure process. In some embodiments, a subsequent structure can be placed or built upon the photo-responsive material. In some cases, the material that formed the initial photo-responsive structure, such as photoresist, can be removed after a subsequent structure is plated, positioned, or built on it, while in other embodiments, the photo-responsive structure can remain in the semiconductor device assembly. Various benefits of providing smoothed 3-dimensional topographies at semiconductor lithographic scales may include improved reflective and/or refractive performance, finer control over movement of micro electro-mechanical system (MEMS), higher-performing inductive and/or capacitive structures, etc.

A further advantage of some embodiments is the ability to fabricate or form smoothed shapes in situ in the semiconductor device assembly. For example, many smoothed surfaces can be formed, such as, but not limited to, sloped, coiled, spiral, helical, half-helical, concave, convex, etc. The smoothed formed structures can thus include MEMS structures, micro-lenses, micro-lens arrays, optical fibers, and probe cards with, for example, cantilevered pins. Devices that are formed with the advantageously smoothed surfaces can achieve improved performance, such as improved electrical performance, optical performance, etc. Where the shape of a structure is used to encode data (e.g., as in optical data storage devices), improved process control of surface smoothing can enable higher areal density of data or even pseudo-analog encoding.

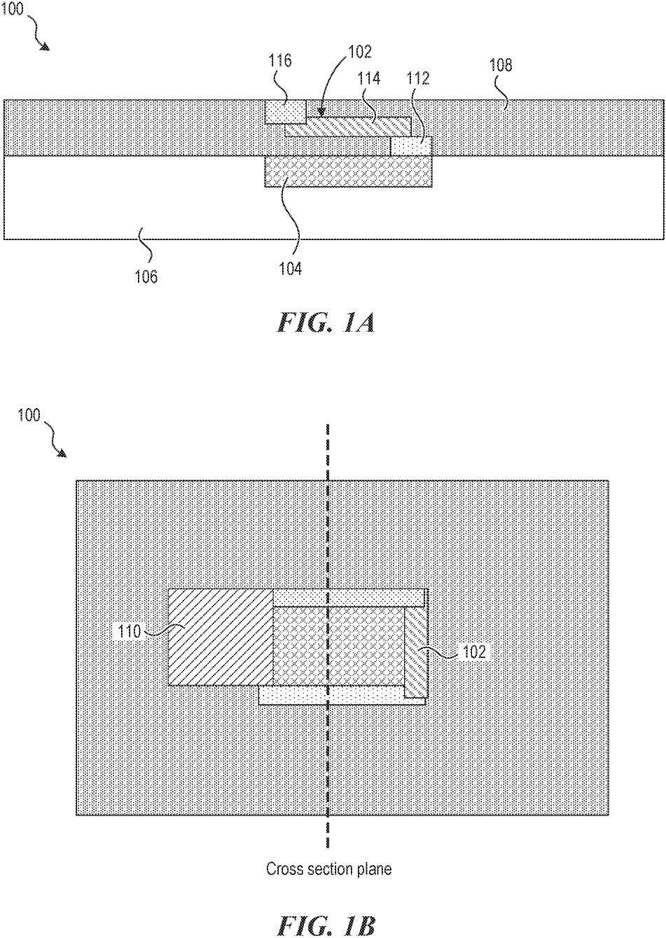

Numerous specific details are disclosed herein to provide a thorough and enabling description of embodiments of the present technology. A person skilled in the art, however, will understand that the technology may have additional embodiments and that the technology may be practiced without several of the details of the embodiments described below with reference to FIGS. 1A-6. For example, some details of semiconductor devices and/or packages well known in the art have been omitted so as not to obscure the present technology. In general, it should be understood that various other devices and systems in addition to those specific embodiments disclosed herein may be within the scope of the present technology.

As used herein, the terms “vertical,” “lateral,” “upper,” “lower,” “above,” and “below”, “top”, and “bottom” can refer to relative directions or positions of features in the semiconductor devices in view of the orientation shown in the Figures. For example, “upper”, “uppermost”, or “top” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation. Also, as used herein, features that are, can, or may be substantially equal are within 10% of each other, or within 5% of each other, or within 2% of each other, or within 1% of each other, or within 0.5% of each other, or within 0.1% of each other, according to various embodiments of the disclosure.

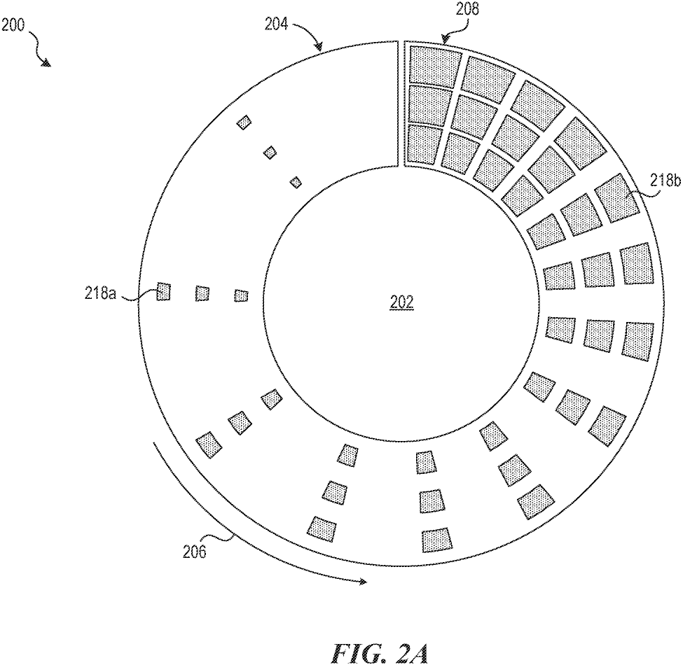

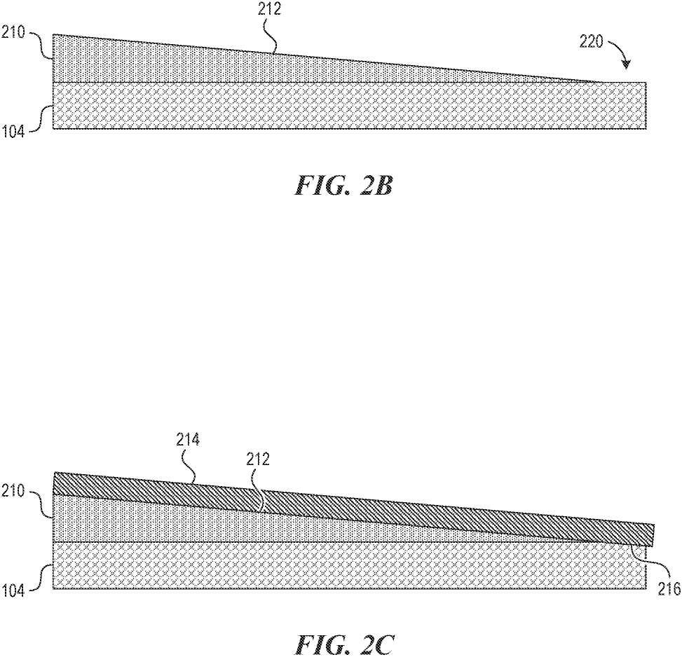

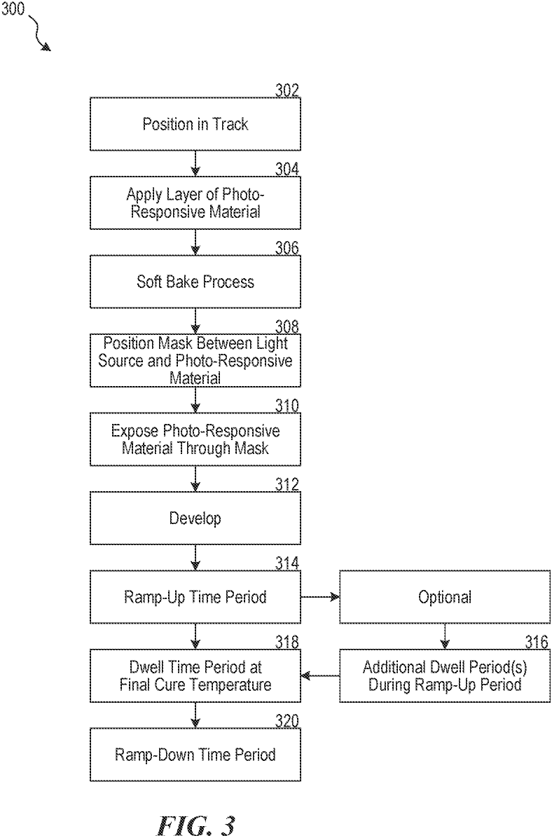

FIGS. 1A and 1B illustrate an overview of a structure that can be formed with the present technology, while FIGS. 2A-6 illustrate further details of the present technology. Like reference numbers relate to similar components and features in FIGS. 1A-6.

FIG. 1A is a cross-sectional view of a semiconductor device assembly 100 that includes a three-dimensional (3D) structure 102 interconnected with a metal pad 104 in or on a substrate 106 in accordance with embodiments of the present technology. FIG. 1B is a top-down view of the assembly 100 and structure 102 of FIG. 1A that indicates the cross-sectional plane corresponding to FIG. 1A. The structure 102 in this example is a partial coil pattern that can be formed over an initial temporary structure (not shown). The temporary structure is formed using grayscale photolithography. The structure 102 can be formed by plating the temporary structure with a conductive or inert material, and then the temporary structure can be removed. Other methods of forming the structure 102 can be used.

The area around the structure 102 can be filled with dielectric material 108 to encase exposed portions of the structure 102. For example, the dielectric material 108 can flow under the structure 102 to fill open areas between the structure 102 and the metal pad 104 and/or substrate 106. The top of the structure 102 can be opened up (such as by grinding, etching, etc.) if needed to form an upper pad 110 for electrical connection to another device or interconnect, as shown in FIG. 1B. The dielectric material can variously include oxides (e.g., SiO, SiO₂), nitrides (e.g., SiN, GaN), silicides (e.g., SiC), ceramics, glass, polymers, plastics, various combinations thereof, or any other dielectric material known to those of skill in the art.

The structure 102 is shown with three different fills to indicate different depths. Portion 112 is attached to or closest to the substrate 106, portion 114 is further from the substrate 106, while portion 116 continues to the surface of the dielectric material 108. This representation is used for ease of illustration only. Although the structure 102 is shown as generally rectilinear, the shape of the structure 102 can instead be curved, such as a smooth coil or spiral-shape with smoothed gradients along its surface that curves from the metal pad 104 to the top portion 116 or top surface of the dielectric material 108. The smooth coil of 3D structure 102 would therefore not have large gradients as shown. The structure 102 can be other 3D shapes, such as helical or circular, convex or concave, ramped, or other shapes as discussed further below. In some embodiments, the structure 102 can be used as a conductive spring-like structure that allows for a slight flex of the structure 102 to improve the connection, thus providing an advantage by preventing the interconnect from cracking when the assembly 100 is used within devices that move or flex.

FIG. 2A is an example of a grayscale gradient mask 200 that can be used to create a sloped, partially coiling structure of photo-responsive material. The gradient mask 200 can have many tones for limiting light transmission from zero to 100 percent transmission. The varying opaqueness of the gradient mask 200 can be generated, for example, by a checkerboard pattern of pixels 218 that uses many squares (or other shapes) of varying size and density. Although only several pixels 218a, 218b are indicated, there can be many more pixels 218 of varying size, shape, and pitch included in the gradient mask 200. The varied amounts of exposure can create different depths of removal of the photo-responsive material.

If a positive-tone photo-responsive material is used, a greater level of light exposure results in a greater removal of material. In some cases, full exposure to light can result in full removal of the photo-responsive material. In contrast, if a negative-tone photo-responsive material is used, exposure to a greater level of light results in removing less of the material.

The gradient mask 200 in FIG. 2A has an “O” shape that can extend in a circular manner up to but not including 360 degrees. If used with positive-tone photo-resist material, areas surrounding the gradient mask 200 and area 202 inside the “O” shape have full exposure and will be subsequently removed. A portion 204 of the gradient mask 200 can allow full exposure. The light exposure by the gradient mask 200 is gradually decreased moving around the “O” shape in the direction of arrow 206 by increasing the number, size, and/or pitch of the pixels 218, such that a portion 208 of the gradient mask 200 can fully or almost fully block the light. For example, the portion 204 that provides a greater exposure to light, resulting in greater removal of the photo-responsive material, can correlate with portion 112 of the 3D structure 102 of FIG. 1A, while the portion 208 that blocks a greater amount of the light can correlate with portion 116 of the structure 102.

An initial structure formed of the photo-responsive material using the gradient mask 200 can be shaped as a partial spiral or helical structure that has a sloped or ramped outer surface. The upper or outer surface can be rough with many stair-steps that result from the varying opaqueness of the gradient mask 200. In some embodiments, a smoother gradient along the surface of the initial structure is desired, and can be accomplished with a smoothing profile during the material curing process as discussed below in FIG. 3.

FIG. 2B illustrates an example of a portion of an initial structure 210 that has been formed using the gradient mask 200 and cured as discussed below in FIG. 3 in accordance with embodiments of the present technology. For example, the initial structure 210 can be formed on the metal pad 104 of the substrate 106. Area 220 can correlate to the portion 204 of the gradient mask 200, resulting in a greater and/or complete removal of the photo-responsive material in the area 220. As discussed below in FIG. 3, the photo-responsive material is cured at a rate to allow the material to cross-flow, creating a smoothed surface 212 of the photo-responsive material of the initial structure 210.

FIG. 2C illustrates a second structure 214 formed over the smoothed surface 212 of the initial structure 210 in accordance with embodiments of the present technology. In some embodiments, the second structure 214 can be made of a material such as polyimide. In other embodiments, the second structure 214 can be conductive, as discussed with respect to the 3D structure 102 of FIG. 1A, and can be plated over the smoothed surface 212 of the initial structure 210. For example, the second structure 214 can be formed of a ductile metal such as gold or indium, although other conductive materials can be used. The second structure 214 can be electrically interconnected to a bond pad (e.g., the metal pad 104 of FIG. 1A), shown as electrical interconnect 216 in FIG. 2C. In some embodiments, the initial structure 210, if made of material such as photoresist, can be removed after the second structure 214 is in place. In some cases, additional layer(s) and/or structure(s) can be formed on or over the second structure 214.

FIG. 3 is a flow-chart of a method 300 for smoothing a gradient of the outer surface of the structure made of the photo-responsive material in accordance with embodiments of the present technology, and will be discussed together with FIGS. 1A, 2A, 4A, and 4B. Subsequent to cleaning and deposition of other materials, such as Aluminum, or the forming of other structures, the substrate 106 (e.g. wafer) can be positioned in a track of a semiconductor photolithography machine/system (not shown) that accomplishes the grayscale photolithography process (block 302). The substrate 106 is coated with a layer of photo-responsive material (block 304). For example, spin-coating can be used to apply an even layer of photo-responsive material (e.g., photoresist material, polyimide material, etc.) across the substrate 106. In some embodiments, a layer of approximately 20 microns can be applied, although other thicknesses can be used.

A soft bake process can be accomplished to “set” the photo-responsive material on the substrate 106 (block 306). The soft bake process is generally a low temperature, low time process that can prevent the slide or migration of the photo-responsive material prior to light exposure. The gradient mask 200 is positioned between a light source and the photo-responsive material, such as with a mask aligner (block 308). In some embodiments, as discussed in FIG. 2A, the gradient mask 200 can be a checkerboard grayscale pattern mask, although other mask patterns can be used. The photo-responsive material is exposed to light, such as ultraviolet light, through the gradient mask 200 (block 310). In some cases, the exposure may involve scanning or stepping the substrate 106 through the machine.

Unwanted photo-responsive material can be removed during a development process (block 312), such as but not limited to, with a solvent. In some embodiments, as discussed previously with respect to FIG. 2A, if a positive-tone photoresist material is used, a greater level of light exposure correlates to a greater removal of photo-responsive material, while the opposite can be the case with negative-tone photoresist material. Similarly, if the photo-responsive material is a polyimide, the amount of polyimide material that is removed can correspond to the amount of light exposure. At this point, the smoothed surface 212 of the photo-responsive material can have nonlinearities or “stair-steps” (e.g., a pixelated stair-step shape) as a result of the gradient mask 200.

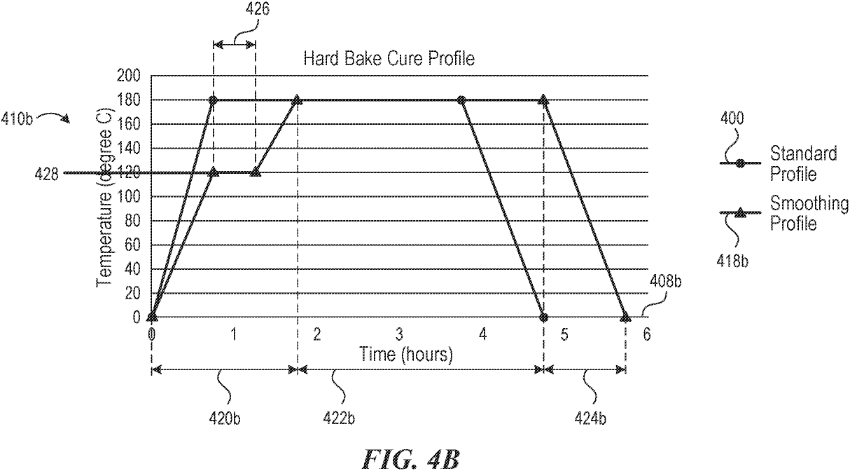

Turning to FIGS. 4A and 4B, these figures show both a standard hard bake cure profile and a smoothing hard bake cure profile for a polyimide material in accordance with embodiments of the present technology. For example, the polyimide material in the example of FIGS. 4A and 4B can be Asahi Kasei PIMEL™ MA-1001, although the embodiments are not limited to this particular material and the use of other polyimide materials is contemplated. It should be understood that the temperature and time parameters can be different based on the particular photo-responsive material used. For example, the photoresist material can be cured in less time than the polyimide material. However, the smoothing cure profiles for other materials can have similar temperature over time profiles to those shown in FIGS. 4A and 4B.

Standard profile 400 is the same in both FIGS. 4A and 4B, and time is indicated along X-axis 408 and temperature is indicated along Y-axis 410. The standard profile 400 indicates temperature change over time during first, second, and third time periods 402, 404, 406 (indicated only on FIG. 4A for clarity). The first time period 402 has an associated ramp-up wherein the temperature is increased from zero degrees Celsius or another starting temperature 412 to a dwell temperature 414. The dwell temperature 414 can be associated with the particular photo-responsive material being processed. The dwell temperature 414 is maintained at a relatively constant temperature for the second time period 404 to cross-link the photo-responsive material, and then the temperature is ramped back down over the third time period 406 to a predetermined finish temperature 416.

Referring to smoothing profile 418a of FIG. 4A while returning to FIG. 3, the temperature is increased or ramped up during first time period 420a (block 314). In some embodiments, an initial temperature can be zero degrees Celsius or other relatively lower starting temperature 412. Although the starting temperature 412 is indicated as the same for the standard profile 400 and smoothing profiles 418a, 418b, different starting temperatures 412 can be used. Over the first time period 420a, the temperature is increased to the dwell temperature 414, which can be the same or substantially the same as the dwell temperature 414 of the standard profile 400. In the example of FIGS. 4A and 4B, the dwell temperature 414 is approximately 180° C.

The first time period 420a (e.g., ramp-up period) of the smoothing profile 418a is longer than the first time period 402 of the standard profile 400. The first time period 420a spends a greater amount of time below the dwell temperature 414 to allow the polyimide material to soften (e.g., melt) and cross-flow before the polyimide material is set or cross-linked during the second time period 422a. The cross-flow of the polyimide material softens the gradients or edges (e.g., corners of the stair-step) that are created in the outer surface of the polyimide material as a result of using the gradient mask 200, resulting in a smoother, more linear, outer surface. In general, a slower ramping rate (e.g., ramping at less degrees per minute) results in more smoothing of the polyimide material while faster ramping, as shown by the standard profile 400 wherein the temperature rises at a relatively greater number of degrees per minute, “sets” the smoothed surface 212 of the polyimide material with the stair-steps and ridges as it was created by the gradient mask 200. Therefore, processing using the standard profile 400 results in larger gradients on a surface of the polyimide material compared to the smoothed surface 212 that results from the smoothing profile 418a.

In some embodiments, the first time period 420a of the smoothing profile 418a can exceed one hour, such as approximately 70 minutes, 80 minutes, 90 minutes, or even more, while the first time period 402 of the standard profile 400 is less than one hour, such as approximately 40 minutes. In other embodiments the first time period 402 of the standard profile 400 can be accomplished in approximately half the time of that of the first time period 420a of the smoothing profile 418a. Relatedly, the temperature of the smoothing profile 418a rises as a slower rate than the standard profile 400, such as at approximately two degrees per minute slower than the standard profile 400. The smoothing profile 418a can rise at a relatively constant rate between the starting temperature 412 and the dwell temperature 414 as shown in FIG. 4A, although the technology is not so limited. Although a single ramp-up rate is shown during the first time period 420a, it should be understood that the temperature and time of the ramp-up rate can vary within a range, such as within a percentage of the rate shown (e.g., up to any of 1%, 2%, 3%, 4%, 5%, etc.) Those of skill in the art will readily appreciate that the temperature and time of the ramp-up rate can be configured, depending upon the material to be smoothed, to ensure that the material softens prior to the formation of cross-links.

Optionally, there may be one or more additional dwell time period, indicated as fourth time period 426 on FIG. 4B, that occurs within the first time period 420b (block 316). During the fourth time period 426, dwell temperature 428 is held relatively constant as shown, such as at approximately 120° C. In other embodiments, the dwell temperature 428 during the fourth time period 426 can be increased or decreased within a predetermined range or percentage of the dwell temperature 428, such as, but not limited to, 1%, 2%, 3%, 4%, 5%, etc., of the dwell temperature 428.

Although not shown, in other embodiments there can be two or more (e.g., three, four, five, etc.) intermittent dwell time periods within the first time period 420a. For example, the smoothing profile 418b can be configured to ramp-up for a period of time and then hold at a first relatively constant temperature for a first intermittent time period. Following a second ramp-up period, the temperature can be held at a second relatively constant temperature for a second intermittent time period before a third ramp-up period to another intermittent temperature or the dwell temperature 414. The smoothing profiles 418a, 418b can therefore be customized to facilitate the desired cross-flow of the photo-responsive material.

In some cases, the smoothing profile 418b during the first time period 420b of FIG. 4B rises at a slower average rate than the smoothing profile 418a during the first time period 420a of FIG. 4A. The first time period 420b of the smoothing profile of FIG. 4B is longer than the first time period 420a of the smoothing profile of FIG. 4A, but the technology is not so limited to the examples shown.

Returning to the method of FIG. 3, the dwell temperature 414 can be held for the second time period 422a, 422b (block 318). In some embodiments, the second time period 404 of the standard profile 400 and the second time period 422a, 422b of the smoothing profile 418 can be the same or similar, while in other embodiments, the second time periods 404, 422a, 422b can be different with respect to each other.

The temperature is then ramped down during the third time period 424a, 424b from the dwell temperature 414 to a predetermined finish temperature (block 320). In some embodiments the predetermined finish temperature can be zero degrees Celsius, while in other embodiments the finish temperature can be approximately the same as or different than the starting temperature. Other start and finish temperatures are contemplated and can be determined based on the characteristics of the photo-responsive material as well as other processes used to create the initial structure 210 (FIGS. 2B, 2C).

While FIGS. 4A and 4B relate to polyimide material, photoresist material can have similar smoothing profiles that also have first time periods that are longer than the first time period of a corresponding standard profile to allow time for the photoresist material to cross-flow at a temperature below the dwell temperature. In some embodiments, the first time period for the smoothing profile for photoresist material can equal or exceed 10 minutes, while the first time period for the standard profile can be in a range of three to five minutes. As discussed previously, multiple intermittent dwell time periods can maintain intermittent temperatures at approximately constant levels during the first time period. The specific time periods can be within a tolerance and are defined based on the photo-responsive material.

It should be understood that there may be other steps in the process of FIG. 3 and that some of the steps may be accomplished in an order different than described. For example, other photo-responsive materials may require additional processing steps, temperature ranges may vary in temperature and/or time, etc.

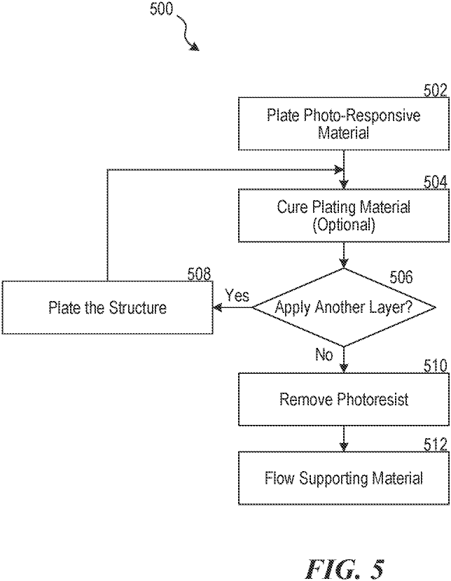

FIG. 5 is a flow-chart of a method 500 for building a structure on top of or over the smoothed structure formed of photo-responsive material in accordance with embodiments of the present technology. Although method 500 is primarily discussed in relation to photoresist (e.g., photo-responsive material that forms a temporary structure that will subsequently be removed after the second structure is formed), some blocks of the method 500 also apply to photo-responsive materials such as polyimide that remain in place in the final semiconductor assembly.

A material such as polyimide, metal, or glass can be used to plate the initial photo-responsive structure (block 502) to form a first structure that has the shape of the initial photoresist structure. For example, the subsequent structure can have the curves, slopes, etc., of the initial photoresist structure. This example was previously discussed with respect to FIG. 2C. The plating material is then cured (block 504) if needed. If an additional layer is to be applied (block 506), such as a layer of metal or glass over an initial polyimide layer, or the addition of a layer of a different material, the previous structure is plated (block 508). The method can return to block 504, wherein curing and/or additional processing of the plated layer(s) can be accomplished.

When all layers are in place, the photoresist material can then be removed using known methods, leaving the subsequent or second structure (block 510). In some embodiments, supporting material, such as a dielectric, can be flowed under and into open areas to encase the second structure (block 512). If a polyimide material has been used to form the initial structure 210 rather than photoresist, the dielectric can be flowed to encase the initial structure 210 and the second structure.

In some embodiments, additional curing steps and/or processing such as etching can be accomplished before applying a layer over the photoresist material (e.g., prior to block 502) and/or between subsequently applied layers of material (e.g., between blocks 506 and 508).

In addition to the curved, sloping structure indicated in FIGS. 1A and 1B, a person of ordinary skill in the art can appreciate that many other 3D structures and shapes can be formed in-situ on the substrate using an appropriately designed gradient mask and the smoothing profile associated with the photo-responsive material. For example, different gradient masks can be made to correlate with a large number of different 3D shapes, including but not limited to: sloped, ramped, spiral, helical, half-helical, convex, concave, etc. From these shapes, reflectors and refractors can be made; sloped, spiral, helical, or half-helical structures can be used to enhance the performance of inductors (e.g., 3D helical inductor). Additional structures include, 3D inductively coupled links (ICL), micro electro-mechanical system (MEMS) structures for sensors and/or accelerometers, RF antennas to enhance RF signals, cooling channels to carry cooling mediums, hyperbolic and/or parabolic curves, sloped structures for creating a lens, arrays of lenses (e.g., micro-lens array such as to form an array of micro-lenses over pixels in complementary metal-oxide-semiconductor (CMOS)), or other optical applications formed in situ.

In some embodiments, a sloped structure for lens or optical applications can be used to form a curved or coiled (e.g., full or partial coil) optical interconnect on top of an optical generator/receiver. Instead of forming a metal coil or partial coil, as discussed with FIG. 1A, the coil can be formed of an optically clear glass-based material, such as or similar to that used to fabricate optical fibers. In some embodiments, a two-coat process can be accomplished with an optical shield of metal lining a curved cavity coil. For example, the initial sloped structure can be a coil or partial coil that has a central cavity extending along a middle portion from the substrate to an upper, outer end. The central cavity can be lined with the metal lining before the glass-based material is applied within the cavity.

A coiled metal structure can be formed on top of a pad that could be used for probe cards. This structure can enable high density array probe cards for an entire array contact (e.g., by keeping the coiled metal structure entirely below the footprint of the pad.

In further embodiments, additional interconnected structures can be built in layers. For example, referring again to FIG. 1A, at least some portions of the methods of FIGS. 3 and 5 can be repeated to continue the ramped, circular structure of the smoothly varying helical coil. Accordingly, more complex structures can be built and/or interconnected using additional grayscale photolithography sessions.

Some applications and/or structures may benefit from further smoothing. After a smooth surface of the 3D photo-responsive material structure is attained using the smoothing profile 418 discussed in FIG. 3, etching may also be used.

In some embodiments, dry etch processing can be used to “transfer” a shape, such as a slope or curve, of the initial structure onto the material below. For example, the initial structure of photo-responsive material has varying thicknesses. Material that is not covered by the photo-responsive material and thus is exposed will begin to be removed immediately. As the etching process removes the photo-responsive material, additional portions of the material below are exposed and will be removed. Therefore, the shape or topology of the photo-responsive structure is transferred to the material below that is not photo-responsive, such as but not limited to film(s), dialectic, or metal. Once the desired shape is created in the material, any remaining photoresist can be removed with wet solvent clean or other process. If desired, a flash or quick isotropic wet etch can then be performed on the remaining structure to smooth out any remaining “stepped” topographies.

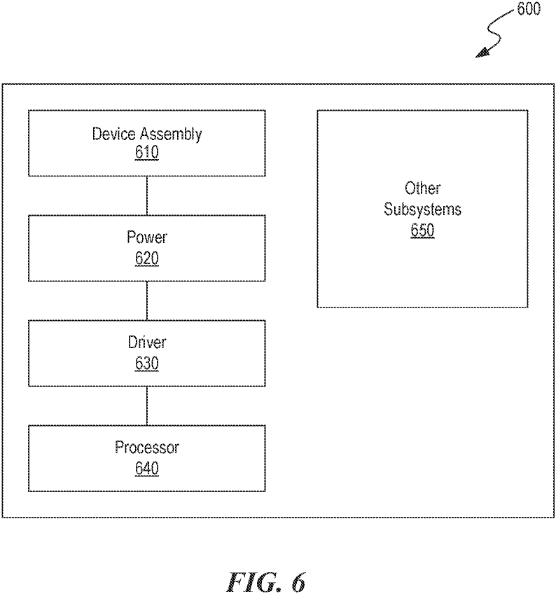

Any one of the semiconductor devices, assemblies, and/or packages described above with reference to FIGS. 1A through 5 can be incorporated into any of a myriad of larger and/or more complex systems, a representative example of which is system 600 shown schematically in FIG. 6. The system 600 can include a semiconductor device assembly 610, a power source 620, a driver 630, a processor 640, and/or other subsystems or components 650. The semiconductor device assembly 610 can include features generally similar to those of the semiconductor device assemblies described above. The resulting system 600 can perform any of a wide variety of functions such as memory storage, data processing, and/or other suitable functions. Accordingly, representative systems 600 can include, without limitation, hand-held devices (e.g., mobile phones, tablets, digital readers, and digital audio players), computers, vehicle and other machines and appliances. Components of the system 600 may be housed in a single unit or distributed over multiple, interconnected units (e.g., through a communications network). The components of the system 600 can also include remote devices and any of a wide variety of computer readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same feature and/or additional types of other features are not precluded. Reference herein to “one embodiment,” “some embodiment,” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

From the foregoing, it will be appreciated that specific embodiments of the present technology have been described herein for purposes of illustration, but that various modifications may be made without deviating from the scope of the invention. The present technology is not limited except as by the appended claims.

I/We claim:

1. A method for smoothing structures formed of curable materials on a semiconductor device, comprising:
applying a layer of photo-responsive material on a substrate;
exposing the photo-responsive material to ultraviolet (UV) light through a grayscale gradient mask; and
subsequent to removing unwanted portions of the photo-responsive material, curing the photo-responsive material that remains on the substrate, the curing comprising:
increasing temperature from a starting temperature to a final cure temperature over a first time period, wherein the starting temperature, the final cure temperature, and the first time period are configured to allow the photo-responsive material to cross-flow prior to hardening or cross-linking;
maintaining the temperature of the photo-responsive material at approximately the final cure temperature for a second time period, wherein the final cure temperature and the second time period are configured to allow the photo-responsive material to harden or cross-link; and
decreasing the temperature of the photo-responsive material to a predetermined finish temperature over a third time period.

2. The method of claim 1, wherein the photo-responsive material is one of positive photoresist or negative photoresist.

3. The method of claim 1, wherein the photo-responsive material comprises a polyimide material.

4. The method of claim 1, wherein the photo-responsive material cross-flows during the first time period whereby a surface roughness of the photo-responsive material is reduced.

5. The method of claim 1, wherein the photo-responsive material is one of positive photoresist or negative photoresist, and the first time period is equal to or greater than 10 minutes.

6. The method of claim 1, further comprising maintaining the temperature approximately at a level between the starting temperature and the final cure temperature for a fourth time period that occurs within the first time period, wherein the fourth time period is at least one minute, and wherein the level of the temperature is maintained to be within a predetermined number of degrees during the fourth time period.

7. The method of claim 1, wherein the temperature is increased from the starting temperature to the final cure temperature over the first time period at a relatively constant rate.

8. The method of claim 1, further comprising removing the unwanted portions of the photo-responsive material with a developer process.

9. A method for forming smooth structures in a semiconductor device assembly, comprising:
applying a layer of photo-responsive material on a substrate;
exposing the photo-responsive material to ultraviolet (UV) light through a grayscale gradient mask;
subsequent to removing unwanted portions of the photo-responsive material, curing the photo-responsive material that remains on the substrate, the curing comprising:
increasing temperature from a starting temperature to a final cure temperature over a first time period, wherein the starting temperature, the final cure temperature, and the first time period are configured to allow the photo-responsive material to cross-flow prior to hardening or cross-linking;
maintaining the temperature of the photo-responsive material at approximately the final cure temperature for a second time period, wherein the final cure temperature and the second time period are configured to allow the photo-responsive material to harden or cross-link; and
decreasing the temperature of the photo-responsive material to a predetermined finish temperature over a third time period; and
forming a structure on a surface of the photo-responsive material, wherein the structure has a shape of the surface of the photo-responsive material.

10. The method of claim 9, wherein the surface of the photo-responsive material is at least one of sloped, ramped, concave, convex, and curved.

11. The method of claim 9, wherein forming the structure comprises depositing a layer of material on the surface of the photo-responsive material.

12. The method of claim 9, wherein the structure is formed of metal, polyimide, glass, or optically-clear glass-based material.

13. The method of claim 9, further comprising removing the photo-responsive material subsequent to forming the structure on the surface of the photo-responsive material.

14. The method of claim 9, further comprising filling an area around the structure that was formed on the surface of the photo-responsive material with dielectric material.

15. The method of claim 9, wherein the photo-responsive material cross-flows during the first time period whereby a surface roughness of the photo-responsive material is reduced.

16. A semiconductor device assembly, comprising:
a substrate;
a three-dimensional (3D) structure formed on the substrate, wherein the 3D structure comprises a smoothed surface of photo-responsive material that has been cross-flowed to reduce a surface roughness thereof during a curing process subsequent to forming the 3D structure on the substrate;
a second structure conformally disposed over the smoothed surface of the 3D structure; and
a dielectric material disposed at least partially over the 3D structure and the second structure.

17. The semiconductor device assembly of claim 16, wherein the 3D structure comprises polyimide.

18. The semiconductor device assembly of claim 16, wherein the second structure comprises metal.

19. The semiconductor device assembly of claim 16, wherein the second structure comprises glass.

20. The semiconductor device assembly of claim 16, wherein the 3D structure is comprised by a electro-mechanical system (MEMS) or an optical lens.
